(19) United States
(12) Patent Application Publication
(10) Pub. No.: US 2009/0192741 A1
(43) Pub. Date: Jul. 30, 2009

(54) METHOD FOR MEASURING FIELD DYNAMICS

(76) Inventor: Mensur Omerbashich, Sarajevo (BA)

Correspondence Address: MENSUR OMERBASHICH, Trg solidarnosti 3/2, Sarajevo, 71000, BA

(21) Appl. No.: 12/022,394

(22) Filed: Jan. 30, 2008

(51) Int. Cl. G01R 23/16

(52) U.S. Cl. 702/76

(57) ABSTRACT

The method patented enables robust and reliable relative measurements of the dynamics of a physical field (or: of a conceptual system). The patented method extends least squares spectral analysis (LSSA) technique's unique features. The LSSA has been proven over the past thirty years as being able of fully replacing the Fourier and Fourier-based spectral analysis methods (as the most used methods of spectral analysis in all sciences). The patented method uses the known feature of the LSSA as a reliable periodicity estimator, and expands its application by claiming its variance-spectral magnitudes are also most useful in terms of their epochal averages (meaning: averages from variance-spectra of data belonging to successive and equal time-intervals) being directly correlated to the energy levels exciting (i.e., supplied into) the field/system. Thus by taking the average (over certain band) spectral magnitude after analyzing datasets that sample a field/system at different instances or/and under various conditions, one can easily and accurately measure the dynamics of the observed field/system in relative terms, using only the changes of such an average.

### BACKGROUND OF THE INVENTION

This patent is of most general utility. It contains a method for easy, accurate, and relative measurement of dynamics of a field (or: of a conceptual system). This invention has direct applicability to most industries such as, but not limited to (NTIS specification in alphabetical order): Biology, Chemistry, Earth Sciences, Economy, Electrotechnology, Genetics, Materials Sciences, Mathematical Sciences, Medicine, Natural Resources, Oil Exploration, and Physics.

The base for this claim is in the following: mean variance-spectral magnitudes of a field that was sampled over a fixed time-interval represent an outstanding descriptor of that field's dynamics. The field's sampling can be organized in a most general way, meaning raw (unaltered and gapped) data can be used with little preprocessing.

For example, I showed in my PhD dissertation (Omerbashich, 2003) (unpublished; copyright reserved entirely) that, when temporal variations of the Earth gravity field are organized into equal time intervals, the mean variance-spectra of so organized field samplings represent that field's dynamics so well as to enable for correlation between Earth oscillation magnitudes and earthquakes' energies to be discerned. This is not seen in power spectra as obtained using classical methods, e.g., Fourier's (using Fourier spectra' power-magnitudes).

In the experiments in which I proved this claim for the total-Earth's (all masses; geophysical noise inclusive) low-frequency (12-120 min) gravity field, the superconducting gravimeter (SG), as the world's most accurate instrument, sampled the field.

I showed based on those samplings that the ratio of Earth's total kinetic energy v. Earth's total seismic energy (i.e., lithospheric portion of the kinetic energy) is constant everywhere throughout the Earth. Thus a successful demonstration in Omerbashich (2003), verified my field descriptor in a global geophysical setup (as the most natural setup on the Earth). Physical meaning for the above finding has been elucidated in Omerbashich (2007).

Thus my descriptor uses noise signature from streams of energy impulses. Since the Earth is the most general and (tidally) forced closed mechanical system—really a stopped up mechanical oscillator—my finding then applies to any physical field too. By extension, the identical principle applies then to any non-physical, conceptual (abstract) system as well, such are systems defined and studied in the areas of economy/finance, genetics, medicine, etc.

Thus I discovered an accurate and undemanding descriptor of field/system's relative dynamics. Furthermore, thanks to this invention, one is now able to discern easily and uniquely any dynamics that is being cyclically superimposed onto the field/system as a whole. This method can have higher efficiency than what can be normally achieved by traditional, say Fourier based approaches.

### BRIEF SUMMARY OF THE INVENTION

A method for relative measurement of the dynamics of a physical field (or: of a conceptual system). Using a series of vectors, where each vector contains field (or: system) samplings taken along the field's selected eigenfrequencies within a fixed band (or: taken for the system's known variations for selected variables) and over certain fixed, say time-, interval, obtain from those series the most accurate and easy (no preprocessing; no post-processing) measurements of that field's (or: of that system's) behavior over time (or: over another selected variable).

### DETAILED DESCRIPTION OF THE INVENTION

The least squares spectral analysis—LSSA by Vaní\check{c}ek (1969, 1971) is a least squares estimation method for computing variance- or power-spectra from any type of numeric or quasi-numeric (originally non-numeric) record of any size and composition. Superiority of optimization in the Euclidean sense offers numerous advantages over using the classical Fourier Spectral Analysis (FSA) for the same purpose (Press et al., 2003). On the other hand, the Fourier spectral analysis and its derivative methods, demonstrated here as inferior to the patented method for the purposes of this patent, are by far the most used techniques of spectral analysis in all sciences.

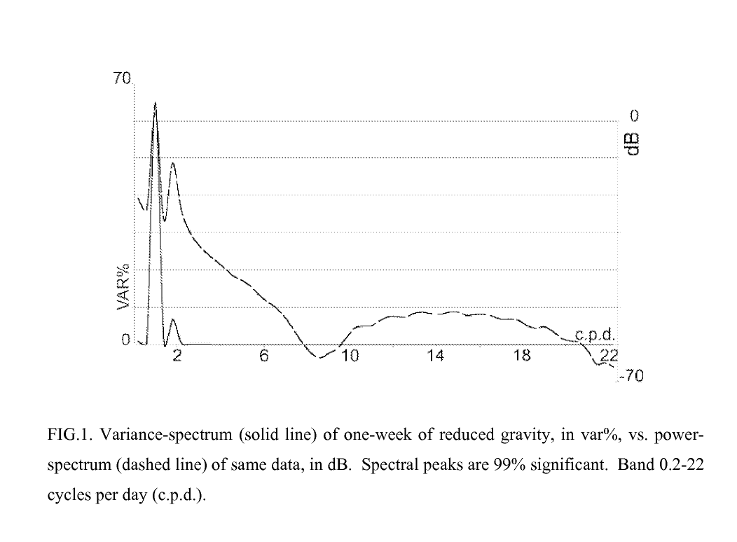

The most important LSSA advantage is its blindness to the existence of gaps in records: least-squares spectral analyses do not require uniformly sampled data, unlike the Fourier spectral analysis and its derivative methods. Neither preprocessing nor post-processing to artificially enhance either the time series (by padding the record with invented data) or its spectrum (by stacking or otherwise augmenting the spectrum), respectively, are required when LSSA is used. Furthermore, the output variance spectrum possesses linear background, i.e., the spectrum is generally zero everywhere except for the periodicities; see FIG. 1. This gives a unique definition and full meaning to the spectral magnitudes within the band of computation.

Unlike any known methods of spectral analysis, the LSSA can be used on virtually any set of numerical or quasi-numerical (originally non-numeric) data, complete or gapped, to produce variance spectrum of those data. This makes it the preferred technique in practically all sciences that deal with inherently discontinuous records, such as: biotechnology, genetics, genetic engineering, chemistry, chemical engineering, physics, geophysics, electronics, electrical engineering, medicine, and medical and diagnostic equipment manufacturing.

Potential benefits from measuring field (system) dynamics accurately by means of spectral analyses of virtually any record are substantial, and are summarized as the common bettering of life quality in general, particularly in economically underdeveloped areas of the world, by providing more efficient industrial tools that rely upon more stable electronic and industrial systems, low-cost medical services and lab testing.

The least-squares spectral estimation is part of the series of least-squares estimation theories started once by Gauss and Legendre, and completed by Vaní\check{c}ek. The LSSA has been developed for the needs of, and subsequently used to a great success in: astronomy, geodesy and geophysics, finance, mathematics, medicine, computing science etc. A test of LSSA on synthetic data can be found in Omerbashich (2003), together with a list of references.

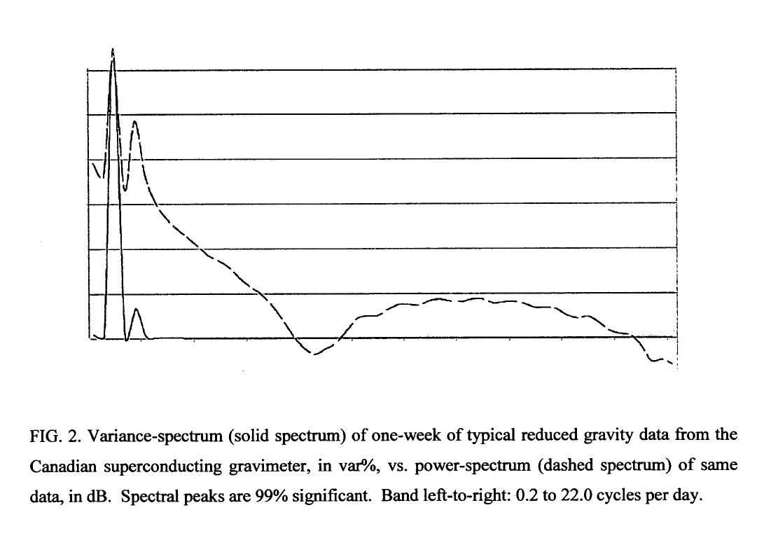

The patented method consists of three steps:
1. Group raw datasets (noise inclusive) into fixed time-intervals, where datasets are composed of sampled temporal (or: determined by some other criteria) variations of a field (or: of a system) along the field's selected normal or natural eigenfrequencies within a fixed band (or: taken for the system's variations for selected variables);
2. Input each group of variations separately into the least-squares spectral analysis to produce each group's variance spectrum, see FIG. 2;
3. Use the series of simple averages taken over a fixed band, of the spectral magnitudes from all groups, i.e., one average per group, as the relative descriptor of the field's (or: of the system's) dynamics represented by those groups. In addition, the averages can be fed back into the spectral analysis to obtain the variance spectrum of variance spectra, which, e.g., can tell of (cyclic nature of) superimposed components of a field/system.

FIG. 1 demonstrates the validity of LSSA as a uniform descriptor of noise levels; having linear (here: zero-var %-level) background over a band of interest everywhere except for statistically significant peaks.

FIG. 2 shows the validity of the simple-average (i.e., taken over a fixed band) LSSA spectral magnitude, as a relative descriptor of the energy supply into a physical field.

The patented method is also supported by the major finding of (Omerbashich, 2003; FIG. 4-30), that, unlike power-spectra, variance-spectra of Earth gravity do correlate with seismic energy, as shown using three geophysical Earth-models and over 15000 computations of cross-correlation between the 12-120 min variance-spectra of Earth total masses' 1.1 billion gravity accelerations, and energy impulses from 400 strong-earthquakes in the decade of 1990-ies.

Here the (gravity) field was sampled by the Canadian SG as a very stable instrument (Merriam, 2000). There are about twenty SG's in operation in the world at the present. They are the most accurate instruments on Earth, and they are used for, amongst other things, verifying the Newtonian constant of gravitation.

All the figures are independent from each other. The above claims are also supported by the included references.

### REFERENCES

Merriam, J. “Reference level stability of the Canadian superconducting gravimeter”. Proceedings of the 14^{th} Annual Symposium on Earth Tides, Mizusawa, Japan (2000).
Omerbashich, M. Earth-model Discrimination Method. Ph.D. thesis, pp. 129. Dept of Geodesy, U of New Brunswick, Fredericton, Canada. Unpublished; copyrights reserved entirely (2003).
Omerbashich, M. Magnification of mantle resonance as a cause of tectonics. Geodinamica Acta (European J of Geodynamics) 20, 6: 369-383 (2007).
Vaní\check{c}ek, P. Approximate Spectral Analysis by Least-squares Fit. Astrophysics and Space Science, 4: 387-391 (1969).
Vaní\check{c}ek, P. Further development and properties of the spectral analysis by least-squares fit. Astrophysics and Space Science, 12: 10-33 (1971).
Press, W. H., Teukolsky, S. A., Vetterling, W. T. & Flannery B. P. Numerical Recipes. Cambridge University Press (2003).
Omerbashich, M. A Gauss-Vaní\check{c}ek Spectral Analysis of the Sepkoski Compendium: No New Life Cycles. Computing in Science and Engineering 8 (4): 26-30, American Institute of Physics & IEEE (2006).

Van Camp, M. Measuring seismic normal modes with the GWRC021 superconducting gravimeter. Phys. Earth Planet. Interiors 116 (1-4), 81-92 (1999).

Having described my invention, what I claim is:

1. Using the described data-non-invading method, measurements can be made of the dynamics (say, change in time) of a physical field (or: of a non-physical, i.e., a conceptual system), which are more reliable than the same measurements that are made using data-invading methods—notably those methods which rely upon the Fourier spectral analysis as the most used spectral analysis methods amongst all such methods in all sciences. The spectra obtained in the here described manner, when applied onto problems from physical sciences, represent the most rigorous field descriptor of all possible field descriptors, enabling accurate and simultaneous measurement of relative dynamics and eigenfrequencies of a physical field (or, in non-physical sciences: enabling reliable measurement of the state changes of a conceptual system, given one or more system variables).

2. The least-squares spectral analysis can be used as a standard spectral-analysis method in all sciences. Namely, since variance-determined (thereby: naturally and directly noise-reflective), the least-squares variance-spectral peaks—employed in the here described manner—represent the most natural way of describing field/system changes. Thus, the results from data-invading spectral analysis methods applied onto natural data, most notably the Fourier spectral analysis methods as the most used ones amongst all such methods in all sciences, can now thanks to the patented method be directly and method-independently checked, say against results from the LSSA of same numerical or quasi-numerical data sequence of interest.

3. Thanks to the patented method, the selection of a procedure normally (meaning: by most researchers) used for preparation of data before feeding the data into a spectral analysis algorithm, can be based on the simplest approach of all: only raw data are required for the herein described method (except for instrument-operation-related filtering used for suppressing of instrumental and immediate-environment noise). In addition, no post-processing interventions into the output (spectra) are needed, unlike with any and all other spectral techniques most notably the Fourier spectral analysis method and its derivative techniques.
